(19) United States
(12) Patent Application Publication
(10) Pub. No.: US 2025/0227964 A1
(43) Pub. Date: Jul. 10, 2025

(54) ENGINEERED QUANTUM PROCESSING ELEMENTS

(71) Applicant: Silicon Quantum Computing Pty Limited, Kensington, New South Wales (AU)

(72) Inventors: Ludwik Kranz, Kensington, New South Wales (AU); Michelle Yvonne Simmons, Kensington, New South Wales (AU); Rajib Rahman, Kensington, New South Wales (AU); Pascal Macha, Kensington, New South Wales (AU); Michael Jones, Kensington, New South Wales (AU)

(73) Assignee: Silicon Quantum Computing Pty Limited, Kensington, New South Wales (AU)

(21) Appl. No.: 18/846,619

(22) PCT Filed: Mar. 14, 2023
(86) PCT No.: PCT/AU2023/050177

§ 371 Date: Sep. 12, 2024

(30) Foreign Application Priority Data
Mar. 14, 2022 (AU) 2022900620

(51) Int. Cl. H10D 48/00; B82Y 10/00; G06N 10/40; G06N 10/70; H10D 48/01

(52) U.S. Cl. CPC H10D 48/3835; B82Y 10/00; G06N 10/40; G06N 10/70; H10D 48/01; H10D 48/385

(57) ABSTRACT

Engineered quantum processing elements are disclosed. The engineered quantum processing element includes a dopant dot embedded in a semiconductor substrate. A dielectric material forms an interface with the semiconductor substrate. The dopant dot includes a plurality of dopant atoms and one or more electrons/holes confined within the dopant dot. The geometrical configuration of the plurality of dopant atoms with respect to the semiconductor substrate is engineered to achieve optimal linear hyperfine Stark coefficients. Further, aspects of the present disclosure are directed to methods of fabricating such engineered quantum processing elements.

### TECHNICAL FIELD

Aspects of the present disclosure are related to quantum processing systems and more particularly to engineered quantum processing elements.

### BACKGROUND

Large-scale quantum processing systems hold the promise of a technological revolution, with the prospect of solving problems, which are out of reach with classical machines. To date, a number of different structures, materials, and architectures have been proposed to implement quantum processing systems and to fabricate their basic information units (quantum bits or qubits). Qubits can be understood as quantum-mechanical systems encoded into two discrete energy levels.

Semiconductor spin qubits have now reached high enough figures of merit to envision error-corrected architectures for quantum information processing, but several outstanding challenges remain to be solved before a viable quantum computing processor can be demonstrated in silicon.

However, before such large-scale quantum computers can be manufactured commercially, a number of hurdles need to be overcome. One such hurdle is control of qubits. To date, several techniques have been proposed to control the states of qubits, but these techniques either cannot be effectively scaled-up or result in faster decoherence. Manipulating spin-based qubits in semiconductors, in particular, performing fast operations on the spin states of qubits is an important avenue for constructing a quantum gate. In particular, fast, individually addressable qubit operations are essential for scalable architectures.

Accordingly, there exists a need for a scalable qubit control system that can simultaneously control multiple qubits while not adversely affecting the operation of the qubits.

### SUMMARY

According to a first aspect of the present invention, there is provided an engineered quantum processing element comprising: a semiconductor substrate; a dielectric material forming an interface with the semiconductor substrate; a dopant dot comprising a plurality of dopant atoms and one or more electrons/holes confined within the dopant dot, wherein geometrical configuration of the plurality of dopant atoms with respect to the semiconductor substrate is engineered to achieve optimal linear hyperfine Stark coefficients.

According to a second aspect of the present invention, there is provided a method of fabricating an engineered quantum processing element, the method comprising: exposing a semiconductor substrate to atomic hydrogen H to form a monolayer of H and passivating the surface of the semiconductor substrate; selectively desorbing H atoms from the passivated surface by the application of appropriate voltages and tunneling currents to an STM tip, forming a plurality of patches in the H monolayer; wherein the distance between the plurality of patches and the orientation of the plurality of patches along a direction of the semiconductor lattice is selected to achieve large linear hyperfine Stark coefficients; and incorporating at least one donor atom in each of the plurality of patches in the H monolayer, to form a donor molecule.

### BRIEF DESCRIPTION OF DRAWINGS

Features and advantages of the present invention will become apparent from the following description of embodiments thereof, by way of example only, with reference to the accompanying drawings, in which:

FIG. 1 illustrates an example spin qubit device 100 formed in a silicon substrate. FIG. 1A is a top view of the donor spin qubit device 100 and FIG. 1B is a side cross-section view.

FIG. 2A shows a plot of the ESR spectral profile or resonance profile of a qubit excited by a 1 MHz Rabi frequency.

FIG. 2B is a plot of the spectator qubit error as a function of the frequency detuning from the target qubit resonance.

FIG. 3A shows an example engineered qubit device.

FIG. 3B shows another example engineered qubit device.

FIGS. 4A-4D show the hyperfine Stark shift for an un-engineered 2P donor dot system.

FIGS. 5A-5D show the hyperfine Stark shift for an engineered 2P donor molecule of the present disclosure.

FIG. 6A depicts the Stark coefficient as a function of inter donor atom distance and inter-donor axis.

FIG. 6B depicts the Stark shift as a function of inter donor atom distance and inter-donor axis.

FIG. 6C shows the electron wavefunction for 2P donor configurations along the [100] and [110] crystal directions.

FIG. 7A shows an STM micrograph image of device.

FIG. 7B is a 3D rendering of the STM topography showing the left quantum dot after P-doping.

FIG. 7C is a top view image showing the position of the three donor atoms in the left quantum dot in the silicon crystal substrate.

FIG. 7D is a schematic energy diagram of the electron-nuclear spin system.

FIGS. 7E and 7F show measured the NMR spectra and the measured ESR spectra for a 2P donor molecule, respectively.

FIG. 8 shows a flowchart illustrating an example method according to aspects of the present disclosure.

FIG. 9A is a plot showing the spectator qubit error.

FIGS. 9B-D show an example of the ESR spectra for a 2P donor quantum dot, as well as the Rabi oscillations of the target and spectator qubits for a hyperfine Stark shift of 26 MHz and a Rabi frequency of 100 kHz.

FIG. 10A is a plot of the qubit error as a function of the peak shift (Stark shift) and gate speed (Rabi frequency).

FIG. 10B shows the qubit error for a 110 MHz Stark shift as a function of the Rabi frequency.

FIG. 11A shows the Stark shift as a function of electric field for an example 2P molecule with the donors separated by 5.4 nm along the [110] direction

FIG. 11B is a plot of the T₂* time due to charge noise as function of the electric field for the 2P donor configuration separated by 5.4 nm along the [110].

FIG. 11C is a plot of the simulated ESR spectra for an electron spin on a 2P molecule initialised in the | [symbol] state for −5 MV/m electric field (peak 1106) and 5 MV/m.

FIG. 11E shows the electron is mostly localized on the spin down nucleus at −5 MV/m

FIG. 11F shows the electron spin is mostly localized on the spin up nucleus at +5 MV/m.

### DETAILED DESCRIPTION

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### Overview

One type of quantum computing system is based on the spin states of individual quantum processing elements, where the quantum processing elements may be electron spins, hole spins, or nuclear spins localized in a semiconductor chip. These electron, hole and/or nuclear spins are confined either in gate-defined quantum dots or on donor or acceptor atoms that are positioned in a semiconductor substrate, and are referred to as quantum bits or qubits.

Donor spin qubits in silicon are a promising platform for a universal quantum computer due to their long coherence times and high fidelity readout, single- and two-qubit gates as well as their advantages in scalability.

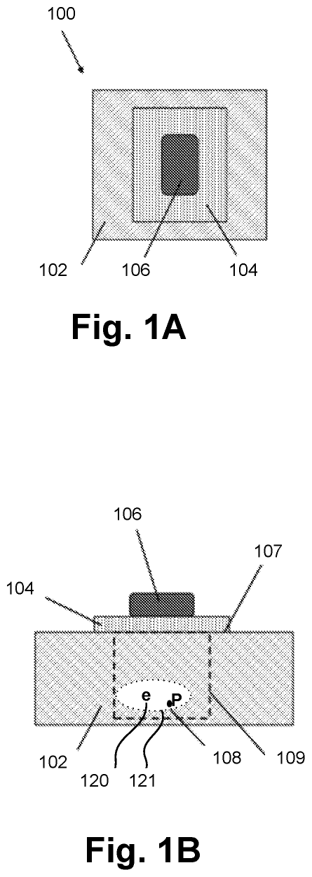

FIG. 1 illustrates an example spin qubit device 100 formed in a silicon substrate. FIG. 1A is a top view of the donor spin qubit device 100 and FIG. 1B is a side cross-section view. The donor spin qubit device 100 may be used for a quantum computer comprising a plurality of these qubits. As shown in the figure, the qubit device 100 is formed in a structure comprising a semiconductor substrate 102 and a dielectric 104. In this example, the substrate is 28Silicon and the dielectric is silicon dioxide. Where the substrate 102 and the dielectric 104 meet an interface 107 is formed. In this example, it is a Si/SiO2 interface. To form the qubit, a donor atom 108 is located within the substrate 102 inside region 109 under a gate 106. The donor atom 108 can be introduced into the substrate using nano-fabrication techniques, such hydrogen lithography provided by scanning-tunneling-microscopes, or the industry-standard ion implantation techniques. In this example, qubit device 100 includes a single atom 108 embedded in the silicon crystal. However, the methods described herein may be applied to qubits devices 100 including clusters of more than one embedded atom 108.

An electron 120 is then loaded onto the device 100 by the gate electrode 106. The physical state of the electron 120 is described by a wavefunction 121—which is defined as the probability amplitude of finding an electron in a certain position. Donor qubits in silicon rely on using the potential well naturally formed by the donor atom nucleus to bind the electron spin.

The gate electrode 106 is located above region 109 and is operable to interact with the donor atom 108. For example, gate electrode 106 may be used to induce an AC electric field in the region between the interface 107 and the donor atom 108 to modulate a hyperfine interaction between the electron 120 and the nucleus of the donor atom 108. The electron wavefunction 121 is mediated by the local fields applied to the gate electrode 106. For example, local fields applied to the gate electrode 106 may pull the electron wavefunction 121 away from, or closer to, the donor 108.

In particular, the AC electric field can be used to control the quantum state of the qubit associated with the spin of the nucleus. Further, the AC electric field works in synergy with an applied oscillating magnetic field.

A key component of a scalable quantum computer is that qubits can be individually addressed to apply quantum gates. However, qubit addressability has been a challenge for donor spin qubit devices 100 since gates 106 are typically implemented either via electron spin resonance (ESR) on nominally identical electron spins or via nuclear magnetic resonance (NMR) on nominally identical nuclear spins, requiring a mechanism for distinguishability.

Addressability of individual donor qubits in silicon was originally proposed through donor Stark shift, utilizing the hyperfine or g-factor Stark shift of the qubit resonance. Stark shift is the splitting of degenerate spin states in the presence of an external electric field and qubit resonance is related to the energy gap separating the two spin states of the qubit that allow for the qubit to be addressed. The spin qubit resonance depends on the Zeeman splitting, which is linearly proportional to the g-factor. Therefore any change in the g-factor will change the qubit resonance. Donor Stark shift is achieved through the application of local electric fields. For example, applying an electric field on gate electrode 106, pulls the electron wavefunction 121 away from the donor 108. This electric field reduces the hyperfine interaction (where the hyperfine interaction is the interaction between the electron spin and the nucleus spin of the donor) and also changes the electron spin g-factor (where the spin g-factor is a dimensionless magnetic moment that characterizes the spin momentum of the electron). This in turn affects the electron spin energy splitting and therefore the qubit resonance frequency.

In one originally proposed method, Stark shift was implemented by applying voltages to the gates 106, to create the required local electric fields at the donor site 109. However, initial experiments on single donors revealed the Stark shift to be much smaller than envisaged. The single donor Stark effect measured was relatively small compared to the (1 MHz/MVm⁻¹) ESR linewidth, restricting single qubit gate operation speeds to the point where gate fidelities are at or just below the surface code error threshold (0.6-1%). Thus in these devices there is a trade-off between speed and fidelity of single qubit gates. High speed qubit gates lead to substantial power broadening of the ESR peak linewidth, inducing interference errors with neighboring qubits, while slower driving leads to qubit decoherence.

Pulse shaping of the Rabi amplitude can be used to improve qubit addressability by reducing the linewidth of the qubit resonance. Rabi amplitude corresponds to the amplitude of the oscillations between a low-energy state and a high-energy state of a qubit and Rabi frequency is the frequency at which the qubit oscillates between the two states. For example, the frequency at which the electron spin qubit oscillates between the spin-down state |↓ [symbol] and the spin-up state |↑ [symbol] .

In some examples, a Gaussian shaped Rabi pulse may be used to improve qubit addressability as it has a higher frequency selectivity compared with other pulse shapes, such as rectangular shaped Rabi pulses.

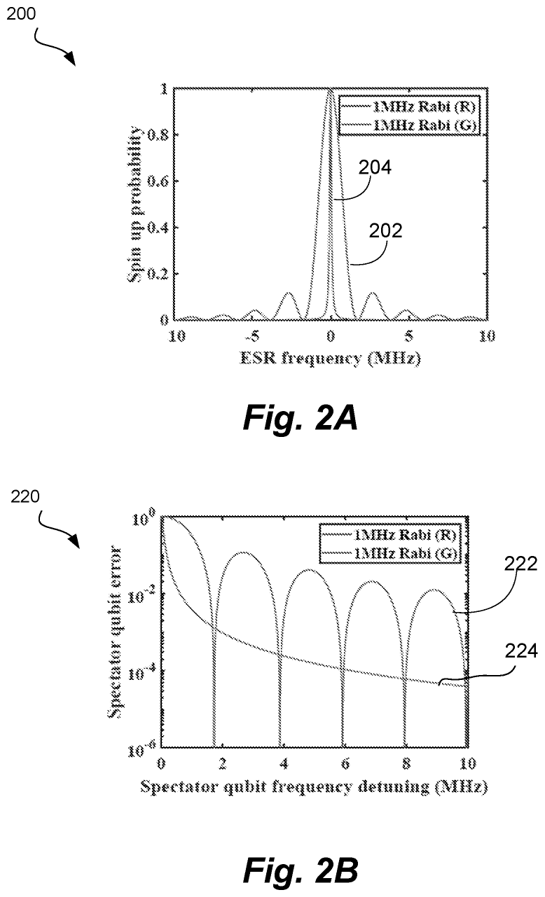

FIG. 2A shows a plot 200 of the ESR spectral profile or resonance profile of a qubit excited by a 1 MHz Rabi frequency—a drive strength typically obtainable in ESR qubit experiments. The x-axis shows the ESR frequency in units of MHz and the y-axis shows the electron spin-up probability. Resonance profile 202 corresponds to a qubit excited by a rectangular shaped Rabi pulse and resonance profile 204 corresponds to a qubit excited by a Gaussian shaped Rabi pulse. In this example, the duration of the Rabi pulse has been set to perform a it rotation of the qubit at zero frequency detuning. Where frequency detuning is defined as the frequency shift between a target qubit—that is, the qubit to be addressed—and a spectator qubit—that is, a neighbouring qubit that is not to be addressed.

For the example rectangle pulse shaped Rabi frequency, the resonance peak exhibits significant power broadening, with a full-width-half-maximum (FWHM) of approximately 1 MHz. For the example Gaussian shaped Rabi frequency, the FWHM resonance is approximately 60 kHz. Thus, the linewidth of resonance profile 204 for the Gaussian shaped Rabi pulse is smaller than the linewidth of the resonance profile 202 for the rectangular shaped Rabi pulse. Further, the rectangular pulse causes significantly more power broadening of the ESR peak than the Gaussian pulse.

FIG. 2B is a plot 220 of the spectator qubit error as a function of the frequency detuning from the target qubit resonance. The x-axis shows the spectator qubit frequency detuning in MHz. This is the detuning of the qubit resonance of the spectator qubit from the qubit resonance of the target qubit. The y-axis shows the spectator qubit error.

Error profile 222 shows the error on the spectator qubit as a function of the detuning from the target qubit resonance for a rectangular shaped Rabi pulse with a 1 MHz Rabi frequency. Error profile 224 shows the error on the spectator qubit as a function of the detuning from the target qubit resonance for a Gaussian shaped Rabi pulse with a 1 MHz Rabi frequency. A frequency shift of approximately 10 MHz is necessary to achieve qubit errors below 1% for the rectangular shape (ignoring the oscillations in the spectra), which falls to approximately 600 kHz for the Gaussian shape. However, it is desirable to achieve qubit error rates<<1%. To achieve this, the spectator qubit must be detuned by >>1 MHz from the target qubit—even with Gaussian pulse shaping, which is not feasible.

Another approach to addressability is ensuring each qubit inherently has a different resonance. For this, multi-donor quantum dots can be used, such that different quantum dots have different donor numbers and donor configurations. This approach does not rely on a Stark shift. Instead it relies on different donor numbers and configurations giving rise to different electron spin resonances. While low errors are possible for a few multi-donor quantum dots on their own, this approach may be difficult to scale to large numbers of qubits due to the finite number of multi-donor dot configurations. In some cases, error rates of ˜10⁻⁴ for a two electron spin qubit system consisting of a 1P and a 2P have been calculated for this approach.

To overcome one or more of the issues identified above, aspects of the present disclosure provide new engineered qubits that combine the originally proposed addressability method with the multi-donor dot proposal. In particular, the engineered qubits of the present disclosure include multiple donor atoms and a single electron shared between the donor atoms. These engineered qubits extend qubit fidelities and speeds by engineering larger Stark coefficients in a pair of quantum dots. Further, in a multi-donor quantum dot system, some aspects of the present disclosure may utilize identical donor configuration for each quantum dot. In such systems, a qubit can be addressed uniquely by applying a local electric field to create a Stark shift on just that qubit. Other examples may utilize different donor configurations for different multi-donor quantum dots in a quantum processing system.

The engineered qubits of the present disclosure can be utilized as electron spin qubits—where quantum information is encoded in the spin of the electron shared between the donor atoms. The engineered qubits can also be utilized a nuclear spin qubits—where quantum information is encoded in the spin of any one of the donor atoms.

In particular, aspects of the present disclosure allow three types of qubit addressability:
Addressing the electron spin qubit by engineering quantum processing element with large Stark shift;
Addressing the electron spin qubit by engineering quantum processing elements with a plurality of donors yielding more frequencies for the same electron in order to avoid frequency crowding in the global field of a large scale device;
Addressing the nuclear spin qubit using ESR (Electron Spin Resonance) peaks both for readout and control.

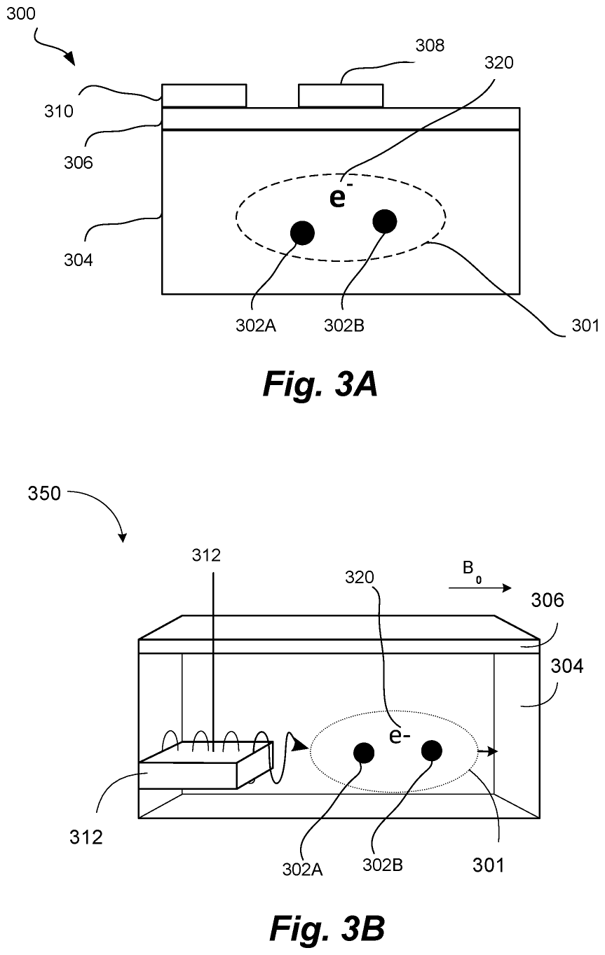

FIG. 3A shows an example engineered qubit device 300. To form the qubit device 300, two donor atoms 302A and 302B are located within a quantum dot 301 in a semiconductor substrate 304. In some example the donor atoms 302A, 302B are phosphorus atoms. In this example, qubit 300 includes two donor atoms 302. The silicon substrate 304 is topped by a barrier material/dielectric 306 such as silicon dioxide. Further, a gate 308 and an antenna 310 may be located on the dielectric 306 in a region above the quantum dot 301. Voltages may be applied to gate 308 to confine an electron 320 in the quantum dot 301. Magnetic fields may be applied via the antenna 310 control the electron and nuclear spin states in the quantum dot 301. The electron 320 may be shared by the two donor atoms 302A, 302B.

FIG. 3B shows another example engineered qubit device 350. This is similar to the device shown in FIG. 3A. The only difference being the placement of the gates. In FIG. 3A, the gate 308 was displayed as being placed on top of the dielectric 306. In this example, one or more gates 312 are located within the semiconductor substrate 304. In some embodiments, the one or more gates 312 are placed within the same plane as the quantum dot 301. The in-plane gates 312 may be connected to the surface 306 of the substrate via metal vias (not shown). Voltages may be applied to gate electrode 312 to confine one or more electrons 320 in the quantum dot 301.

In some devices the in-plane gate electrode 312 is made of phosphorus doped silicon (˜0.25 ML doping density).

In such engineered qubit devices 300, 350 large hyperfine Stark coefficients can be seen. The large hyperfine Stark coefficients are a result of a large hyperfine coupling and electric dipole moment in the 2P donor dot compared to single donors.

The quantum dot 301 with a single confined electron is referred to as donor molecule herein. When the donor atoms are phosphorus atoms, the quantum dot 301 is referred to as an mP donor molecule, where m represents the number of phosphorus atoms in the donor molecule. M can be any number greater than 1.

It will be appreciated that although FIGS. 3A and 3B show a single quantum dot, this is just merely an example. In some embodiments, a plurality of quantum dots 301, and/or 350 can be arranged in a two dimensional or three dimensional structure to create a large scale quantum processor.

Further, although FIGS. 3A and 3B show 2P donor molecules, the engineered qubits of the present disclosure are not restricted to this. Instead, the engineered qubits may include donor molecules that include more than two donor atoms.

Aspects of the present disclosure engineer not only the donor positions but also the donor orientations within a mP donor molecules to achieve large linear hyperfine Stark coefficients. In a 2P donor molecule, linear hyperfine Start coefficients as large as ˜70 MHz/MVm−1 can be achieved (assuming Gaussian pulse shapes), allowing >99.9998% single qubit gate fidelities for a 2pi rotation gate with ˜0.5 μs gate operation times.

These and other advantages of the presently disclosed qubit device and control/operation techniques will be described in detail in the following sections.

### Position and Orientation of the Donors Affecting Stark Shift.

As described above, aspects of the present disclosure relate to engineering optimal Stark coefficients in mP donor molecule systems—for example, in a 2P or 3P molecule system. The large hyperfine Stark coefficients are a result of the large hyperfine coupling and electric dipole moment in the donor molecules as compared to single donor systems. The hyperfine Stark coefficient is a measure of the change in the hyperfine interaction between the donor electron and nucleus with electric field. It has units of MHz/MVm−1.

In particular, inventors of the present invention have identified that certain positions and orientations of donor atoms in a donor molecule result in optimal Stark shifts for controlling and addressing these nuclear spin qubits.

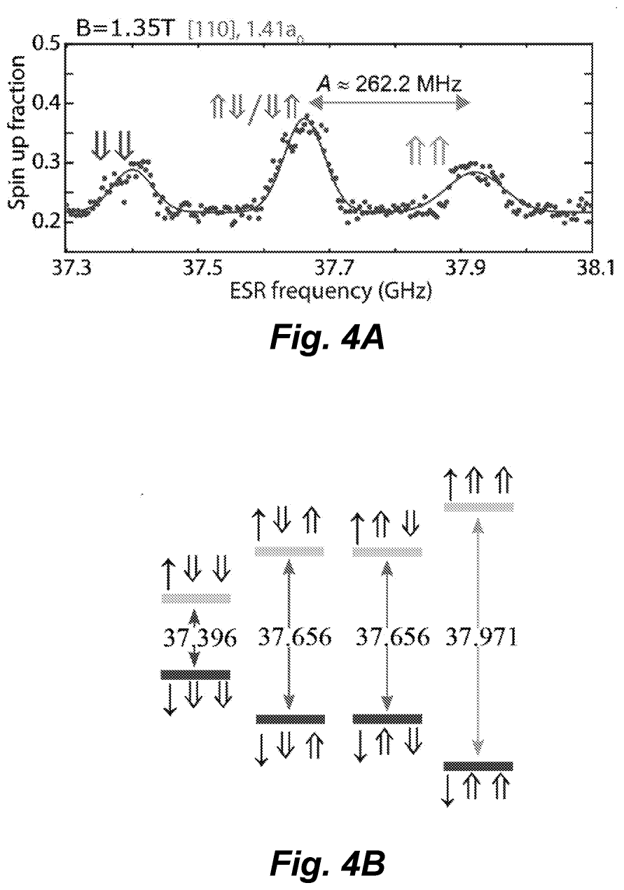

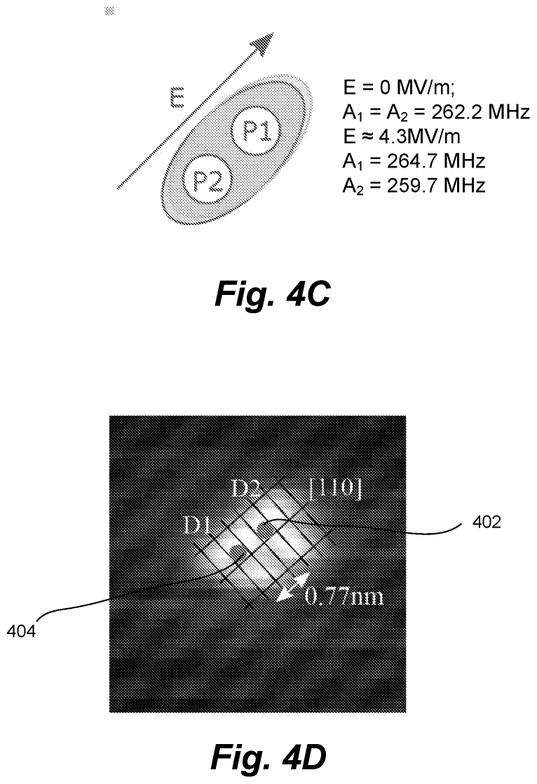

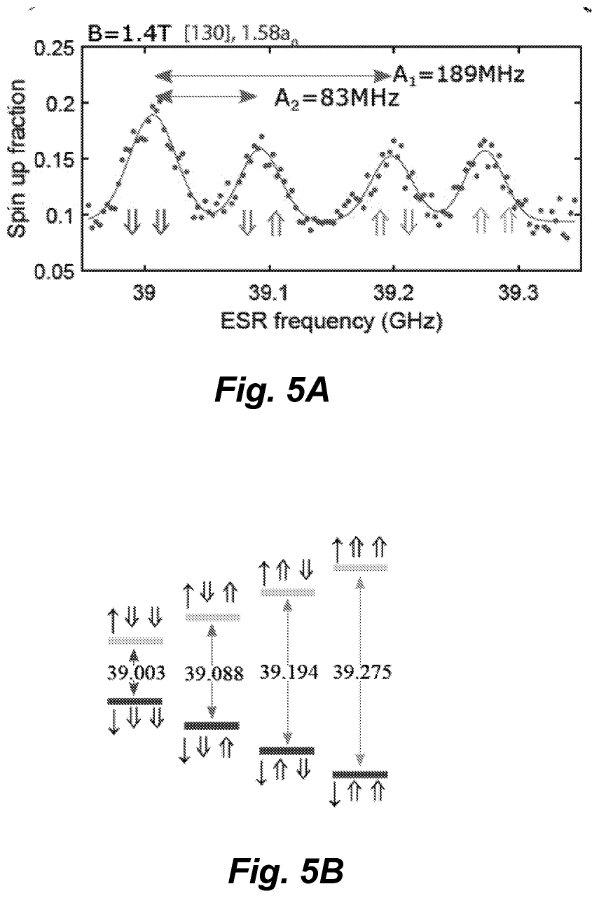

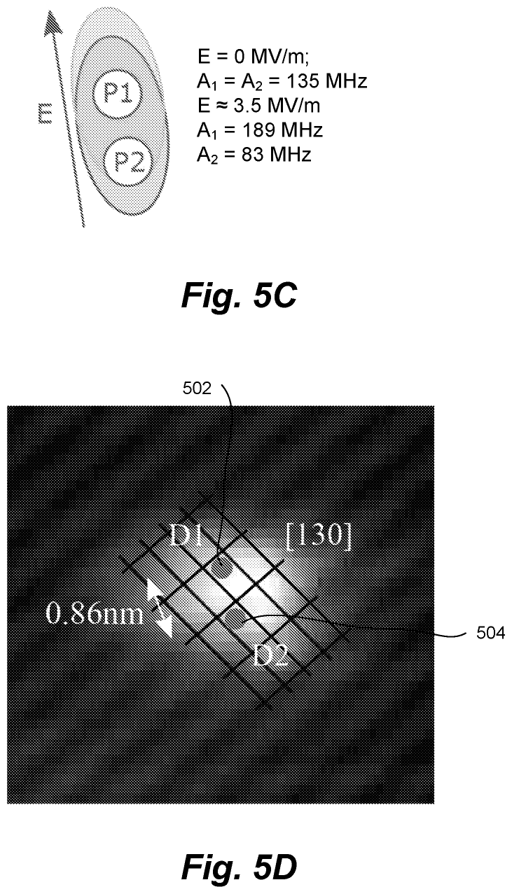

FIGS. 4A-4D show the hyperfine Stark shift for an un-engineered 2P donor dot system and FIGS. 5A-5D show the hyperfine Stark shift for an engineered 2P donor molecule of the present disclosure.

In particular, FIG. 4A shows an electron spin resonance (ESR) spectra for a non-engineered 2P donor dot in natural silicon—with three resonance peaks. The x-axis shows the ESR frequency in GHz and the y-axis plots the spin-up fraction. Further, the nuclear spin states | [symbol] and | [symbol] denote the left and right nuclear spins of the two donor atoms in the dot, respectively. Where the up and down arrow correspond to an up and down nuclear spin state of the donor atoms. In a 2P donor dot system, the donor atoms may be referred to as P1 and P2, respectively.

The lowest frequency peak in FIG. 4A is from the | [symbol] two phosphorus donor nuclear spin state, while the highest frequency peak belongs to the | [symbol] nuclear spin state. The middle peak is twice the height of the lowest and highest frequency peaks and belongs to the | [symbol] and | [symbol] nuclear spin states, which are degenerate within the peak linewidth—with a FWHM of 72 MHz.

FIG. 4B shows a corresponding energy diagram of the total spin states of an example 2P system. The four lower-energy states correspond to total spin states | [symbol] , | [symbol] , | [symbol] and | [symbol] . The four upper-energy states correspond to total spin states | [symbol] , | [symbol] , | [symbol] and | [symbol] . Where | [symbol] and | [symbol] represent a nuclear down-spin and up-spin, respectively and ↓ and ↑ represent an electron spin-down and spin-up, respectively. The ESR resonance frequencies between nuclear spin states in this example non-engineered 2P donor dot are also shown in FIG. 4B.

The degeneracy between the | [symbol] and | [symbol] nuclear spin states results from the electron wavefunction overlapping the two donors equally. Electric fields in the device can break the degeneracy through the Stark effect by shifting the electron wavefunction closer to one of the donors. However the Stark coefficient for this non-engineered 2P quantum dot configuration is small (˜1.7 MHz/MVm−1) and subsequently the Stark shift was not measurable. In this system the nuclear spin and the electron spin cannot be addressed because the Stark shift is too small. Here the | [symbol] and | [symbol] nuclear spin states are degenerate and so the total spin states | [symbol] and | [symbol] are degenerate and similarly, total spin states | [symbol] and | [symbol] are degenerate.

FIG. 4C shows a schematic of the electron wavefunction (blue/yellow ovals) over the two phosphorus donor atoms—P1 and P2. At zero electric field along the donor separation axis the electron 20 is evenly shared between the donors P1, P2 (blue oval), while at the electric fields used in the measurement (˜4.3 MV/m) the electron wavefunction is slightly more localized at donor P1 (yellow oval), resulting in a small <7 MHz hyperfine Stark shift.

FIG. 4D shows the most likely donor configuration for this non-engineered 2P quantum dot device that would yield the ESR spectra shown in FIG. 4A. Here, the two phosphorus donors (402 and 404) are separated by 0.77 nm along the [110] crystal axis. Where the [110] crystal axis corresponds to one unit on the x-axis, one unit on the y-axis and zero units along the z-axis, respectively. For this example non-engineered 2P molecule along the [110] the available electric field in the device (˜5.4 MV/m) could allow a maximum Stark shift of >7 MHz. However, since the electric field was not aligned directly along the donor axis but shifted by ˜40°, the Stark shift would be smaller at ˜5 MHz. This small Stark shift is insufficient to exceed the 72 MHz peak linewidth observed in these natural silicon devices so no Stark shift observed in the ESR spectra.

FIG. 5A an ESR spectra for an engineered qubit device according to aspects of the present disclosure. The x-axis shows the ESR frequency in GHz and the y-axis plots the spin-up fraction. For this engineered qubit device, the ESR spectra shows four resonance peaks, one for each of the | [symbol] , | [symbol] , | [symbol] and | [symbol] nuclear spin states. Here the | [symbol] , | [symbol] nuclear spin states are not degenerate. As such, the engineered 2P quantum dot has four unique electron spin resonances. The four ESR peaks may be fitted with Gaussian functions to extract a FWHM of 44 MHz as a result of a ±20 MHz chirp. This means that to measure ESR spectra so-called adiabatic inversion pulses can be used, where the ESR frequency is linearly swept from −20 MHz to +20 MHz with respect to the carrier frequency.

The four resonances are also consistent with a 2P donor number, since each nuclear spin state (four in total for a 2P) has a unique hyperfine interaction with the electron spin. The spectra is symmetric about the center, such that the splitting between the first and second peaks in FIG. 5A is the same size as between the third and fourth peaks. Thus two hyperfine interactions can be extracted from the spectra, A₁=189 MHz, and A₂=83 MHz, which correspond to the hyperfine interaction between the electron spin and the first and second donor nuclear spins, giving a hyperfine Stark shift A₁−A₂=106 MHz. This hyperfine Stark shift breaks the degeneracy between the donor nuclear spin | [symbol] and | [symbol] states, giving rise to the four ESR transitions shown in FIG. 5A.

Due to the Stark shift breaking the degeneracy of the | [symbol] and | [symbol] states—the four nuclear spin sates may now be individually addressed. Each of the nuclear spin states | [symbol] , c and | [symbol] may be addressed by their corresponding individual ESR frequency. The ESR frequency for each of the | [symbol] , | [symbol] , | [symbol] and | [symbol] nuclear spin states is shown on the x-axis of FIG. 5A.

Further, for this donor configuration the electron qubit may also be addressed. The nuclear spins are initialised in one of the degenerate states | [symbol] , | [symbol] . When an electric field is applied these states become non degenerate because of the Stark shift, such that the ESR frequency is now different from non-Stark shifted qubits. Faster electron addressability may be achieved by very large Stark Shifts—this effectively yields a large ESR frequency different between the | [symbol] , | [symbol] , | [symbol] , | [symbol] nuclear spin states. Electron spin addressability on a 2P system is optimized by maximizing the size of the Stark shift.

In some embodiments, there is provided a plurality of engineered multi-donor quantum dots. In such embodiments the multi-donor quantum dots may each have different number of donor atoms. In some embodiment the multi-donor dots may each have different numbers of donor atoms. In other embodiments, the multi-donor quantum dots may have a combination of the same number or different numbers of donor atoms. The electron qubit of one of the plurality of the multi-donor quantum dots may be addressed by applying the ESR frequency specific to that electron qubit.

FIG. 5B shows the relative energies of the total spin states and the ESR transitions between them. Again, the four lower-energy states correspond to total spin states | [symbol] , | [symbol] , | [symbol] and | [symbol] . The four upper-energy states correspond to total spin states | [symbol] , | [symbol] , | [symbol] and | [symbol] . Due to the optimal stark shift being present in this example engineered quantum processing element the degeneracy of and the | [symbol] and | [symbol] , and the | [symbol] and | [symbol] states are lifted.

FIG. 5C shows a schematic of the electron wavefunction (blue/yellow ovals) over the two phosphorus donor atoms—P1 and P2. At zero electric field along the donor separation axis, the electron is evenly shared between the donors (blue oval), while at the electric fields used in the measurement (˜3.5 MV/m) the electron wavefunction is a lot more localized at donor P1 (yellow oval), resulting in a large hyperfine Stark shift. The larger Stark shift in FIG. 5C compared to FIG. 4C is a result of the different donor configurations in the engineered molecule qubit of the present disclosure.

In particular, donor configuration refers to the donor separation and the orientation of the donors with respect the crystal axis. In some examples, the donors may align their orientation with respect to crystallographic axis. For example, a pair of adjacent donor atoms may be positioned along a crystallographic axis such as [110]. In other examples the adjacent donors may be not be aligned with respect to a crystallographic axes. Instead, they may be positioned at arbitrary positions in the crystal lattice structure.

FIG. 5D shows the most likely donor configuration for this example engineered 2P quantum dot device that would yield the ESR spectra shown in FIG. 5A and associated with a total hyperfine coupling, A₁+A₂. Here, the two donor atoms (502 and 504) are separated by 0.86 nm along the [130] crystal axis which yields a total hyperfine interaction of 276 MHz. The theoretically determined value for the total hyperfine interaction of 276 MHz is in good agreement with experimentally determined total hyperfine interactions of 272 MHz.

Table 1 below shows the different donor configurations with the closest match to the total hyperfine value obtained from the ESR spectra, along with the values of the linear Stark coefficient. From Table 1, it may be observed that the donor configuration along [130] crystal axis has the largest Stark coefficient of 11.2 MHz/MVm−1. This is a factor of between two to three times larger compared with most other configurations. This configuration corresponds to the configuration shown in FIG. 5D and is an example donor configuration that can be engineered for a donor molecule qubit to give rise to large Stark shifts.

All other configurations would require unrealistic electric fields (>10 MV/m, as shown in the final column in Table 1) to achieve the large Stark shift observed and/or have a larger difference between the total hyperfine splitting predicted and the experimental value.

TABLE I
Determination of the most likely 2P donor configuration
for the molecule in FIG. 2 e).

| | | Linear Stark | |
|---|---|---|---|
| Donor | Total hyperfine | coefficient | Electric field |
| configuration | A₁ + A₂ (MHz) | (MHz/MVm⁻¹) | (MV/m) |
| 0.5a₀[130] | 276 | 11.2 | 9.5 |
| 2a₀[100] | 283 | 3.2 | 33.1 |
| 1.5a₀[110] | 284 | 3.6 | 29.4 |
| 0.25a₀[711] | 258 | 9.9 | 10.7 |
| 0.5a₀[411] | 275 | 3.1 | 34.2 |
| 0.5a₀[321] | 263 | 5.3 | 20 |

The inventors of the present disclosure have identified that the exact 2P donor configuration, as well as the orientation and size of the electric field, play a critical role in determining the size of the hyperfine Stark shift.

The ability to engineer these larger hyperfine Stark shifts above 110 MHz may be utilized for faster, fault tolerant single qubit gates that are addressable with a global ESR field. First, the hyperfine Stark shift separates the degenerate | [symbol] /| [symbol] peak into two non-degenerate peaks, while the | [symbol] and | [symbol] nuclear spin states are unaffected by the hyperfine Stark shift, as shown in the ESR spectra in FIGS. 4A and 5A. It is therefore important to initialize the nuclear spins in an anti-parallel state to control the ESR frequency through the hyperfine Stark shift. The phosphorus nuclear spin state in silicon is very stable, with lifetimes on the order of minutes, whereas operations on the electron spin can be performed on the order of a micro-second. Therefore, many operations can be performed on the electron spin without needing to reinitialize the nuclear spins.

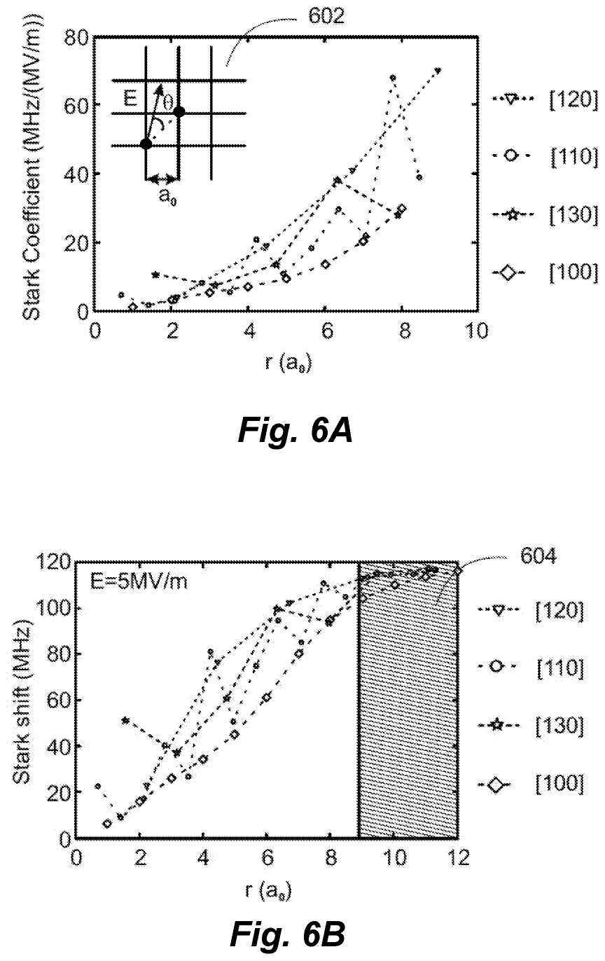

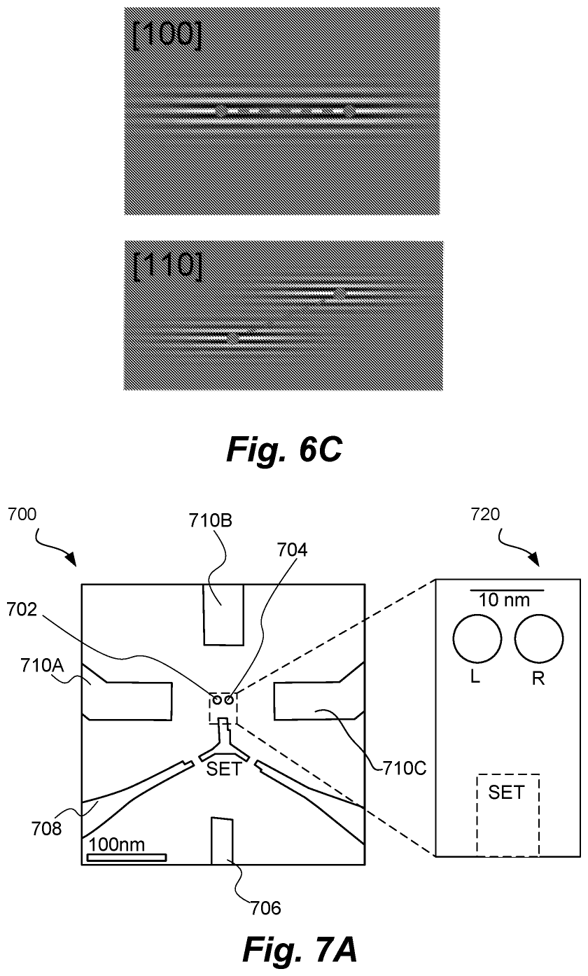

FIGS. 6A and 6B show the simulated hyperfine Stark shift for a single electron 120 in various 2P donor molecule configurations. In particular, FIG. 6A depicts the Stark coefficient as a function of inter donor atom distance and inter-donor axis and FIG. 6B depicts the Stark shift as a function of inter donor atom distance and inter-donor axis.

The simulations of FIGS. 6A and 6B use an atomistic tight-binding model (a nearest neighbor only interactions model) to review all 2P configurations within an 8a₀ by 8a₀ box in the device plane, containing 144 configurations in total (with 80 unique configurations due to the symmetry about the [110] axis). Where a₀ is the silicon atomic lattice constant of 0.543 nm and all 2P donor combinations within a domain of 8×8 atomic lattice sites were looked at.

The x-axes in FIGS. 6A and 6B show the distance between the two donor atoms in units of a₀ —the silicon atomic lattice constant. The y-axis in FIG. 6A shows the simulated Stark coefficient in units of MHz/(MV/m)). The size of the linear Stark coefficient is determined by the location of the second donor atom, P2, relative to the first donor atom, P1. Inset 602 shows a first donor at the (X, Y)=(0,0) and a second donor a distance r from the first donor atom. Further, for FIG. 6A, the Stark coefficient is taken at 0 MV/m electric field strength, while in FIG. 6B the Stark shift is for an electric field of 5 MV/m. Both figures assume the electric field is applied via one or more gates 308, 312 along the inter-donor axis (θ=0°)—this is the axis connecting the first donor with the second donor. The Stark shift=Stark coefficient×electric field

In this simulation, the electric field is applied via one or more gates 308, 312 along the inter-donor axis (θ=0°)—this is the axis connecting the first donor with the second donor.

Further, FIG. 6A shows the simulated results for the Stark coefficient as a function of donor position within the X-Y plane, where the first donor is located at (0,0) (see 502) and the second donor is placed a distance r along the [100], [110], [120], and [130] crystal directions. For each crystal axis, the Stark coefficient increases with donor separation since the electron-donor dipole moment increases, making it more sensitive to electric fields. Oscillations in the Stark coefficient occurs along the [110] and [130] directions due to valley interference along these directions. The linear hyperfine Stark coefficient is also observed to increase non-monotonically due to the presence of the valley interference. Along these crystal directions, the electron exists in a superposition across both donors, with oscillations in its wavefunction due to the presence of the underlying silicon crystal lattice. Valleys here refers to the energy minima in the conduction band. In silicon there are six degenerate minima, also called valleys, which for a single donor electron is in an equal superposition across the six valleys. For two closely spaced donors the electron wavefunction overlaps both donors. Valley components of the electron wavefunction from each donor can interfere with each other either constructively or destructively depending on the exact donor separation and the crystal direction and thus changing the overall wave function.

FIG. 6C shows the electron wavefunction for 2P donor configurations along the [100] and [110] directions to further explain the valley interferences. Along the [100] (and equivalent) directions, the electron wavefunction superposition interferes constructively with separation between the 2P donors. However, if the donors are separated along the [110] crystal direction, destructive interference can occur for certain donor separations. In particular, both X and Y valleys cause constructive and destructive interference of the electron wave function as the specific donor location changes, causing the hyperfine Stark coefficient to oscillate. This anisotropy of the electron wavefunction interference originates from the anisotropy of the silicon effective mass, where each valley orbital has a smaller wavefunction envelope along the longitudinal direction and a larger radius along the transverse direction. This valley interference of the electron wavefunction can couple through the electron-donor dipole moment and the energy of the electron anti-bonding state to produce oscillations in the hyperfine Stark coefficient in the [110] and [130] direction from the monotonic trend.

FIG. 6B is a plot of the Stark shift for different 2P configurations for an electric field of 5 MV/m along the donor separation axis. The y-axis in this plot shows the Stark shift in MHz. The first donor is located at (0,0) and the second donor is placed a distance r along the [100], [110], [120], and [130] crystal directions.

The shaded region 604 of FIG. 6B shows the 2P donor configurations where the Stark shift is 110±5 MHz. For each configuration this occurs when the second donor is located over 8.5a₀ (˜4.6 nm) away from the first donor. This result indicates that the hyperfine Stark shift on 2P donors when they are separated more than 4.6 nm is insensitive to the dopant positioning along the crystal lattice. These donor configurations are easily patterned within the ±1 lattice site precision of STM lithography. Further, 2P donor configurations with smaller inter-donor separations show larger variations in the Stark shift for 5 MV/m electric fields since the size of the Stark shift is not limited by the total hyperfine interaction and therefore is more susceptible to variations in the hyperfine Stark coefficient.

As seen in FIG. 6A, for donor separations below 2a₀≈1 nm the hyperfine Stark coefficient is generally limited to approximately 1 MHz/MVm−1 for most inter donor axes, comparable to the Stark shift observed in a single donor system (e.g., as shown in FIG. 1). In contrast, the 2P donor configuration separated by 1.58a₀ (0.86 nm) along the [130] direction has a linear hyperfine Stark coefficient of 11.2 MHz/MVm−1. This larger hyperfine Stark coefficient, by a factor of 10 for the same donor separation along a different crystallographic direction is due to the presence of the valley interferences described above.

However, not only does the inter-donor crystalline direction matter, but so does the inter-donor separation. Extending the donor separation several lattice sites beyond 2a₀, gives rise to linear Stark coefficients above 70 MHz/MVm−1, as seen along the [110] and [120] directions.

Such large zero-electric field linear Stark coefficients can lead to regimes in which the Stark shift is limited by the size of the total hyperfine coupling with relatively small electric fields. It is largest (679 MHz) for the 0.5a₀ [110] 2P configuration (the nearest donor separation possible) and rapidly declines towards ˜110 MHz with increasing donor separation. For some example devices, electric fields of 5 MV/m can typically be realized and for donor configurations with separations above approximately 8.5a₀ (4.6 nm) the maximum Stark shift of these devices becomes limited by the total hyperfine interaction at this electric field.

Accordingly, it is possible to engineer hyperfine Stark shifts of 105 MHz within a 7.6% tolerance, due to the ±1 lattice site fabrication uncertainty, by targeting the 6a₀ [110] 2P configuration. In particular, the 6a0[110] configuration has the second phosphorus donor separated by 6 lattice constants (a₀) in the x direction and the y direction. Since a₀=0.543 nm, this works out to a separation of 4.6 nm along the [110] or ˜8.5 a₀ along the [110] in atomic lattice units. This is just within the region 604 of FIG. 6B. Moreover, 2P donor configurations with smaller separations show larger variations in the Stark shift at 5 MV/m electric fields since the total hyperfine interaction is larger and therefore the size of the Stark shift is more susceptible to variations in the hyperfine Stark coefficient.

While the simulations of FIGS. 6A and 6B have restricted the position of the second donor to be along the [100], [110], [120], and [130] crystal directions—it is important to note that the second donor can occupy any other lattice site or lattice orientation.

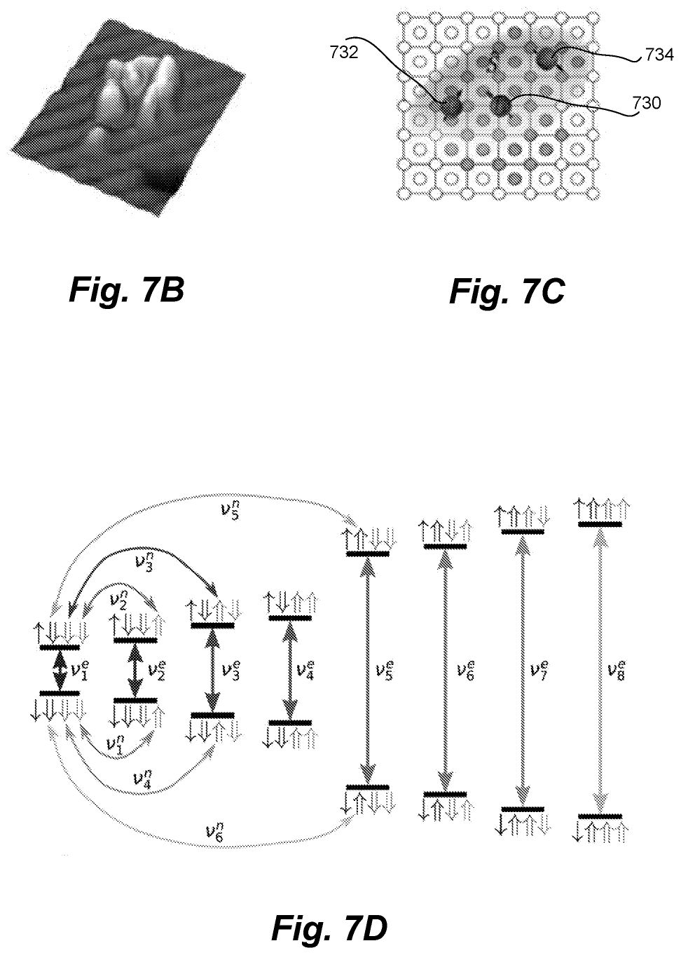

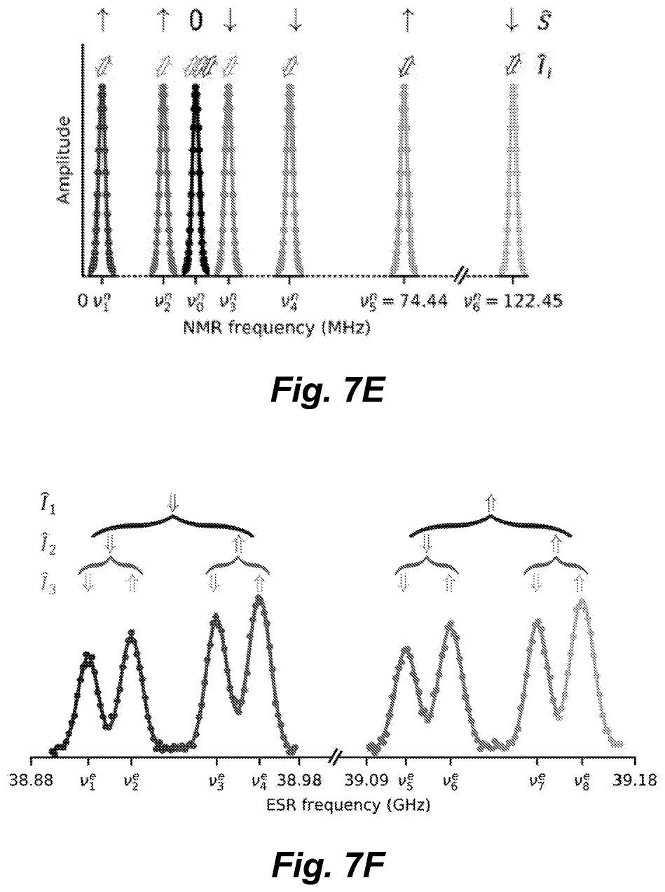

FIGS. 7A-E show a 3P donor quantum dot system, where the donor molecule includes three donor atoms. In particular, FIG. 7A shows an STM micrograph image of device 700 including a left (L) quantum dot 702 and a right (R) quantum dot 704 in isotopically pure silicon-28 with 120 ppm silicon-29. Quantum dots 702A and 702B may be tunnel coupled to a charge sensor 706 (such as a single-electron transistor SET) and electron reservoir 608 to load the electrons onto the donor dots. 720 shows a blown up part of the device 700 with left (L) and right (R) quantum dots shown separated by 10 nm.

The left quantum dot 702 is an engineered quantum dot according to aspects of the present disclosure and includes 3 donor atoms. Left quantum dot 702 is an engineered 3P quantum dot. In this example, the right quantum dot 704 may be engineered or may be a conventional dot without departing from the scope of the present disclosure. Also included in device 700 are gates left gate 710A, middle gate 710B and right gate 610C, which can be used to control the electrochemical potentials of the donor dots 704 and 706. Whereas the SET gate 706 is predominately used to control the electrochemical potential of the SET. Image

FIGS. 7B and 7C are schematic illustrations representing the 3P donor system with one electron confined therein. The position of the 3 donor atoms are labelled I₁, I₂, I₃ (730, 732, 734) and the electron wavefunction is labelled S. In particular, FIG. 7B is a 3D rendering of the STM topography showing the left quantum dot after P-doping and FIG. 7C is a top view image showing the position of the three donor atoms in the silicon crystal substrate.

In this example, two donors (P1 and P2) are positioned along a crystal axis and are separated by a distance along that axis. The third donor (P3) is positioned in another crystal axis and is separated from P1 by a first distance and separated from P2 by a second distance. In some embodiments the distance from P3 to P1 and P2, respectively, may be the same. The geometric orientation of the 3 donors in the 3P system comprises the relative distances between the donors as well as the angles between them. Where the orientation of the donor-molecule is defined by the relative positions of the three donors.

FIG. 7D is a schematic energy diagram of the electron-nuclear spin system. The energy level split due to different Zeeman and hyperfine couplings of the different spin configurations. The arrows correspond to the NMR (νᵢⁿ) and ESR (νᵢ^{e}) transitions.

FIGS. 7E and 7F show measured NMR spectra and the measured ESR spectra, respectively. These are the frequencies that allow nuclear or electron spins to be individually addressed. The NMR spectrum has 6 peaks corresponding to a single nuclear spin flip in each electron spin state (illustrated by the curved arrows in FIG. 7D. Only transitions from | [symbol] | [symbol] | [symbol] are indicated in FIG. 7D. Further, the NMR spectra has another peak corresponding to the transition when the quantum dot is ionized and all the spins are driven at the same frequency. The spectral resolution does not allow observing splittings by nuclear-nuclear interactions. The ESR spectrum features 8 peaks corresponding to the transitions between the 2³=8 possible nuclear spin configurations (illustrated by the vertical arrows in FIG. 7D) annotated in the figure.

### Fabrication of the 2P Donors in a Specific Configuration

Once the donor configurations have been determined for optimal Stark shift for addressing the nuclear spin qubit or the electron spin qubit, a donor quantum dot qubit can be fabricated. In one example, the Stark shift values for different donor numbers, and configurations (separation distance and orientation) can be determined. These values may be stored in a lookup table or database. Depending on the type of addressability required and the corresponding optimal Stark shift values desired, a lookup may be performed in the lookup table/database to identify the number of donor atoms and their configuration. This information can then be used to engineer quantum processing devices. In particular, using methods of fabrication according to aspects of this disclosure allows for precisely placement of the donor atoms in the silicon substrate to create engineered qubits.

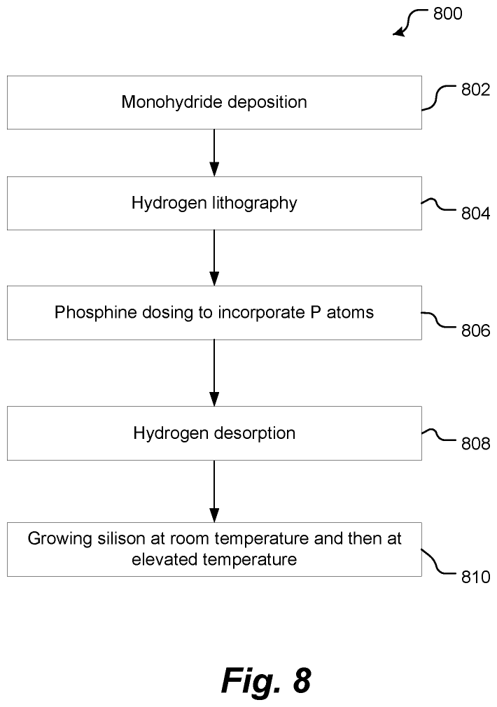

FIG. 8 shows a flowchart illustrating an example method 800 for engineering a qubit device (e.g., including multiple 2P molecules 300) with optimal Stark shift for addressability according to aspects of the present disclosure.

Initially, a clean Si 2×1 surface is formed in an ultra-high-vacuum (UHV) by heating to near the melting point. This surface has a 2×1 unit cell and consists of rows of σ-bonded Si dimers with the remaining dangling bond on each Si atom forming a weak π-bond with the other Si atom of the dimer of which it comprises.

Next, at step 802, (i.e., monohydride deposition) the clean Si 2×1 surface is exposed to atomic H to break the weak Si π-bonds, allowing H atoms to bond to the Si dangling bonds. Under controlled conditions a monolayer of H can be formed with one H atom bonded to each Si atom, satisfying the reactive dangling bonds, effectively passivating the surface.

Next, at step 804 (i.e., hydrogen lithography), an STM tip is used to selectively desorb H atoms from the passivated surface by the application of appropriate voltages and tunneling currents, forming a pattern in the H resist.

It will be appreciated that H atoms are desorbed from precise locations and in precise directions such that donor molecules can be placed in precise locations to achieve high Stark shifts in the presence of electric fields. For example, if a donor molecule is to include two donor atoms spaced 12 lattice sites or 4.6 nm apart along the [110] direction, the STM tip may be used to desorb six hydrogen atoms at one location along a dimer row and then desorb six additional hydrogen atoms 4.5 nm apart along the same dimer row from the first location.

This process is repeated to create positions for other donor molecule sites. In this way regions of bare, reactive Si atoms are exposed along dimer rows, allowing the subsequent adsorption of reactive species directly to the Si surface.

Returning to FIG. 8, at step 806 (i.e., PH₃ dosing), phosphine (PH₃) gas is introduced into the vacuum system via a controlled leak valve connected to a specially designed phosphine micro-dosing system. The phosphine molecule bonds strongly to the exposed Si surface, through the holes in the hydrogen resist). As noted previously, at a particular donor site, a phosphine molecule may bond with any one of the exposed silicon dimers.

Subsequent heating of the STM patterned surface for crystal growth causes the dissociation of the phosphine molecules and results in the incorporation of P into the exposed layer of Si. It is therefore the exposure of an STM patterned H passivated surface to PH3 that is used to produce the required donor molecules.

The hydrogen may then be desorbed, at step 808, before overgrowing the surface with silicon at room temperature, at step 810. An alternative is to grow the silicon directly through the hydrogen layer. The surface is then rapidly annealed.

Silicon is then grown on the surface at elevated temperature. In one example, approximately 50±5 nm of epitaxial silicon is grown at a temperature of 250° C.

Once the required amount of silicon is grown, a barrier may be grown. Finally a microwave antenna may be aligned on the surface using electron beam lithography. Using etched registration markers, the antenna is aligned at a lateral distance of 300±50 nm from the buried donor molecules to produce an oscillating magnetic field Bi perpendicular to the substrate at the donors' position.

Gates may be positioned on the silicon substrate along with the antenna. Alternatively, gates may be positioned in the same plane as the donor molecules. In such examples, the gates may be formed of Si:P during the H desorption phase.

### Optimal Stark Shift for Faster Fault Tolerant Single Qubit Gates

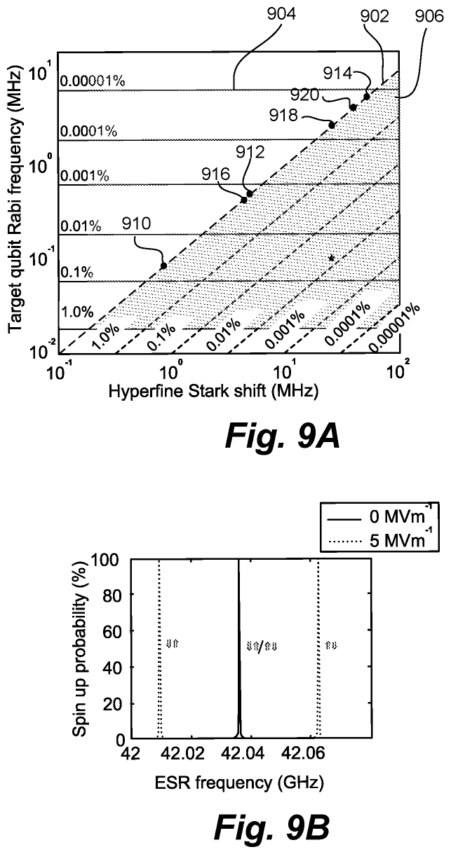

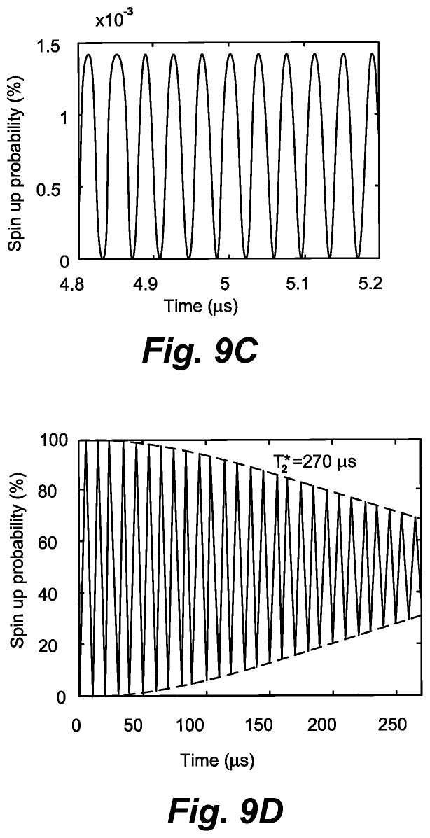

FIG. 9A shows the spectator qubit error percentage (in dashed lines 902)—which is the probability of exciting an off resonance qubit—P(t), as a function of the hyperfine Stark shift of the nuclear spin | [symbol] /| [symbol] ESR peak and the target qubit Rabi frequency, according to the Rabi equation given below:

$$P ( t ) = {( \frac{{g}_{e} {μ}_{B} {B}_{a c}}{h γ} )}^{2} {sin}^{2} ( 2 πγ t ) \qquad ( 1 )$$

$$Where γ = \sqrt{{( \frac{{g}_{e} {μ}_{B} {B}_{a c}}{h} )}^{2} + {( δν )}^{2}} ,$$

B_{ac} is the magnetic field amplitude from the microwave antenna 210, δν is the offset from the resonant frequency of the peak (see below), gₑ is the electron g-factor, and μ_{B} is the Bohr magneton.

Here δν corresponds to the hyperfine Stark shift (or more precisely the size of the frequency shift from the centre of the Stark shifted | [symbol] /| [symbol] ESR peak to the center of the non-Stark shifted | [symbol] /| [symbol] ESR peak). The spectator qubit error P(t) can be evaluated, and the probability of inverting a spectator qubit from spin down to up, at time t=¼γ, i.e. half the period of the Rabi cycle at the Rabi frequency of the detuned spectator qubit. The Rabi frequency of the target qubit is equal

$${( \frac{{q}_{e} {μ}_{B} {B}_{a c}}{h γ} )}^{2}$$

which is swept on the y-axis of FIG. 3A.

The probability of exciting an off resonance spectator qubit is proportional to the overlap of the target qubit ESR peak with the spectator qubit resonance frequency. This can be understood from eq. (1), since the prefactor

$$\frac{{g}_{e} {μ}_{B} {B}_{a c}}{h} ,$$

is a Lorenzian with full-width-half-maximum (FWHM) proportional to B_{ac} on the y-axis of FIG. 3A—showing the frequency f of the Rabi oscillations.

Taking f=0 as the target qubit ESR frequency and f=δν as the spectator qubit ESR frequency, separated by the Stark shift, implies larger Stark shifts reduce the overlap of the Lorentzian with the spectator qubit resonance frequency. Hence, larger hyperfine Stark shifts result in lower spectator qubit errors (as seen in FIG. 9A). Conversely, increasing the AC magnetic field strength, B_{AC}, increases the Lorentzian FWHM (as well as increases the target qubit Rabi frequency), resulting in more overlap of the Lorentzian at the spectator qubit resonance and consequently a higher spectator qubit error rate.

FIG. 9A also illustrates the qubit dephasing error T₂* (as shown by solid lines 904), which for single phosphorus donors in silicon-28 has been measured as long as 270 μs. The dephasing error is estimated from the qubit gate quality factor, as the ratio of the gate time divided by the coherence time, which depends on the Rabi frequency. The dephasing error for the 270 μs dephasing time is plotted for 0.1% and 1.0% values by the solid lines 904. These form lower bounds for setting the target qubit Rabi frequency, since otherwise the target qubit Rabi frequency may be set arbitrarily low to minimize the spectator qubit error, which is indicated by the dashed lines 902 for 0.01%, 0.1%, and 1.0% error probabilities. The shaded triangle 906 signifies the region where both the spectator qubit and dephasing qubit errors are within 1%, approximately the error rate threshold of the surface code.

FIG. 9A also shows how different 2P and 1P donor configurations perform by plotting the size of the hyperfine Stark shift at a 5 MV/m electric field for each of the configurations. The 1P donor shown as dot 910 has the smallest hyperfine Stark shift, which restricts how fast the Rabi frequency can be performed fault tolerantly on the target 1P donor electron spins, when compared with 2P donors.

We note the hyperfine Stark shift for the 1P donor is too small to allow addressable, fault tolerant single qubit operations. However if the g-factor Stark shift is additionally included for a 1.5T magnetic field (see dot 912), then the combined g-factor and hyperfine Stark shift is large enough (5 MHz) to allow addressable, fault tolerant qubit operations at 5 MV/m electric fields. For the 4.61 nm [110] 2P configuration (shown by dot 914), the tight binding simulations predict the hyperfine Stark shift can be engineered to be an order of magnitude larger at 53 MHz, allowing qubit Rabi frequencies of up to ≈5.3 MHz and within the 1% surface code fault tolerance limit. The experiments also indicate the Stark shifts of other 2P donor configurations, such as the 0.77 nm [110] (dot 916), 0.86 nm [130] (dot 918), and 2.30 nm [110] (dot 920) configurations shown previously in FIG. 4D and FIG. 5D respectfully.

While these configurations show larger hyperfine Stark shifts than the 1P donor, the 4.61 nm [110] 2P configuration (dot 914) is more optimal for a large scale architecture, since it can achieve a larger Stark shift and the Stark shift is more robust to fabrication tolerances.

FIGS. 9B-D show an example of the ESR spectra for a 2P donor quantum dot, as well as the Rabi oscillations of the target and spectator qubits for a hyperfine Stark shift of 26 MHz and a Rabi frequency of 100 kHz. This position is indicated by the * in FIG. 9A. Here the target qubit has been rotated from down to up (at 5 μs) with 99.98% fidelity, while there is a ˜0.0015% probability that the spectator qubit is erroneously rotated from down to up.

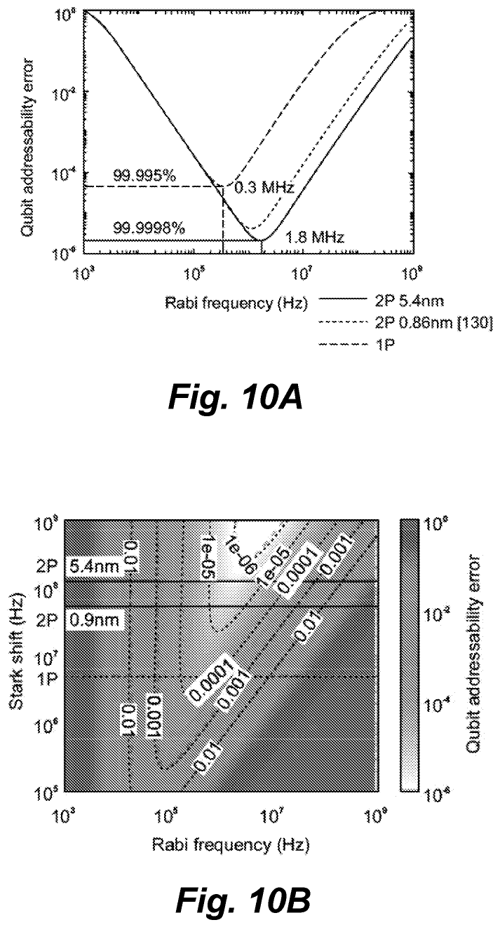

FIG. 10A is a plot of the qubit error as a function of the peak shift (Stark shift) and gate speed (Rabi frequency). Larger Stark shifts result in lower qubit addressability errors, with optimal speeds shown by the dashed red line regions. The qubit error for a 110 MHz Stark shift as a function of the Rabi frequency is shown in FIG. 10B. For a 430 kHz Rabi frequency, <0.01% errors are possible, well below the 1% error threshold of a surface code.

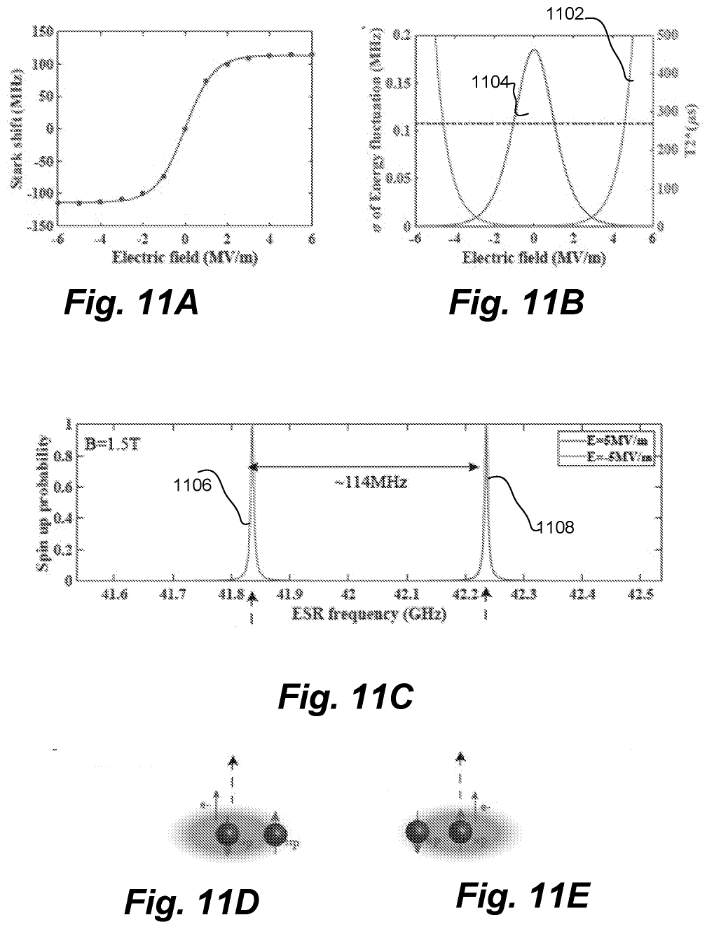

FIG. 11A shows the Stark shift as a function of electric field for example 2P molecule with the donors separated by 5.4 nm along the [110] direction. Each point is taken from the tight-binding simulation of this 2P donor configuration for different electric fields along the donor axis. At zero electric field the Stark shift is zero, since the electron spin is equally shared between the donors and the Stark coefficient is approximately linear. At zero electric field the Stark coefficient is very large (84 MHz/MVm−1). By increasing the electric field the electron spin becomes more localized at one of the donors. Above ±5 MHV/m the Stark shift saturates ±114 MHz and the Stark coefficient is ≈0 as the electron is completely localized.

Large Stark coefficients, while advantageous for qubit addressability, can increase the dephasing of the qubit due to charge noise. By performing simulations of charge noise in example devices, the sensitivity of the electron spin coherence to charge noise may be estimated.

FIG. 11B is a plot of the T₂* time due to charge noise as function of the electric field (curve 1102) for the 2P donor configuration separated by 5.4 nm along the [110]. Curve 1104 is the standard deviation of the electron spin qubit energy fluctuations, which are obtained by taking the derivative of the hyperbolic tangent functions fitted to the Stark shift data in FIG. 11A, multiplied by E_{σx}, the standard deviation of the fluctuating electric fields, which is obtained from a charge noise simulation. The qubit energy fluctuations from charge noise are largest where the Stark coefficient is maximum and consequently the T₂* time is smallest here. The black dotted line crossing through T₂*=270 μs represents the threshold at which charge noise limits the qubit coherence time, since 270 μs is the longest measured coherence time of an electron spin on a single phosphorus donor in silicon. Operating the electron spin qubit in the charge noise sweet spots where the Stark shift saturates (above +/−4.6 MV/m) should ensure that the qubit dephasing is not limited by charge noise.

FIG. 11C is a plot of the simulated ESR spectra for an electron spin on a 2P molecule initialised in the | [symbol] state for −5 MV/m electric field (peak 1106) and 5 MV/m (peak 1108). At −5 MV/m the electron is mostly localized on the spin down nucleus—see FIG. 11E, and the ESR peak is lower in frequency. At +5 MV/m the electron spin is mostly localized on the spin up nucleus (see FIG. 11F) and the ESR peak is shifted up by 114 MHz. These provide two states for the electron spin qubit where the −5 MV/m state can be off the global ESR resonance frequency and the +5 MV/m state can be on resonance, or vice versa.

Although the engineered qubits described here refer to donor molecules, they are not restricted to donor molecules. Instead, the presently disclosed systems and methods can be utilized to create engineered qubits that include other multi dopant molecules, such as multi acceptor molecules. In such molecules, instead of confining a single electron, a single hole may be confined in the multi acceptor molecules.

Further, although the quantum processing systems described herein have been shown with gate electrodes for controlling corresponding qubits, these may not always be necessary. In other embodiments and examples other control means may be utilized without departing from the scope of the present disclosure.

The present embodiments are, therefore, to be considered in all respects as illustrative and not restrictive.

As used herein, except where the context requires otherwise, the term “comprise” and variations of the term, such as “comprising”, “comprises” and “comprised”, are not intended to exclude further additives, components, integers or steps.

1. An engineered quantum processing element comprising:
a semiconductor substrate;
a dielectric material forming an interface with the semiconductor substrate;
a dopant dot comprising a plurality of dopant atoms and one or more electrons/holes confined within the dopant dot, wherein geometrical configuration of the plurality of dopant atoms with respect to the semiconductor substrate is engineered to achieve optimal linear hyperfine Stark coefficients.

2. The engineered quantum processing element of claim 1, wherein the distance between the plurality of dopant atoms and the orientation of the plurality of dopant atoms with respect to each other and the semiconductor substrate are engineered to achieve optimal linear hyperfine Stark coefficients.

3. The engineered quantum processing element of claim 1 or 2, wherein the distance between the plurality of dopant atoms and the orientation of the plurality of dopant atoms within the semiconductor substrate are engineered to achieve linear hyperfine Stark coefficient of approximately ten or more MHz/MVm⁻¹.

4. The engineered quantum processing element of any one of claims 1-3 wherein the dopant dot comprises two donor atoms.

5. The engineered quantum processing element of any one of claims 1-3, wherein the dopant dot comprises three donor atoms.

6. The engineered quantum processing element of any one of claims 4-5, wherein the donor atoms are phosphorus atoms.

7. The engineered quantum processing element of any one of claims 1-6, wherein the distance between adjacent dopant atoms is up to 30 nanometers.

8. The engineered quantum processing element of any one of claims 1-7, wherein the distance between adjacent dopant atoms is up to 6 nanometers.

9. The engineered quantum processing element of claim 8, wherein the distance between adjacent dopant atoms is between 3-5 nanometers.

10. The engineered quantum processing element of claim 9, wherein the adjacent dopant atoms are positioned along the [110] crystal axis of the semiconductor substrate.

11. The quantum processing element of claim 10, having a Stark shift of about 105 MHz and a 5 MV/m electric field.

12. The quantum processing element of any one of claims 1-8, wherein the distance between the dopant atoms is between 0.5-1 nanometer.

13. The quantum processing element of claim 12, wherein the dopant atoms are positioned along the [130] crystal axis of the semiconductor substrate.

14. A quantum processing system comprising a plurality of the engineered quantum processing elements of any one of claims 1-13.

15. A method of fabricating an engineered quantum processing element, the method comprising:
exposing a semiconductor substrate to atomic hydrogen H to form a monolayer of H and passivating the surface of the semiconductor substrate;
selectively desorbing H atoms from the passivated surface by the application of appropriate voltages and tunneling currents to an STM tip, forming a plurality of patches in the H monolayer; wherein the distance between the plurality of patches and the orientation of the plurality of patches along a direction of the semiconductor lattice is selected to achieve large linear hyperfine Stark coefficients; and
incorporating at least one donor atom in each of the plurality of patches in the H monolayer, to form a donor molecule.

16. The method of fabricating of claim 15, further comprising:
desorbing the hydrogen monolayer;
overgrowing the surface with a layer of the semiconductor.

17. The method of fabricating of any one of claims 15 or 16, wherein selectively desorbing H atoms further comprises desorbing H atoms to create one or more patches for creating one or more in-plane gates.

18. The method of fabricating of any one of claims 15 or 16, further comprising:
depositing one or more gates above the positions of the donor atoms.

19. The method of fabricating of claim 18 further comprising: applying a voltage to the one or more gates to cause an electron to be confined in the donor molecule.

20. The method of fabricating of any one of claims 15-19, wherein the distance between the plurality of patches within the semiconductor substrate are engineered to achieve linear hyperfine Stark coefficient of approximately ten or more MHz/MVm⁻¹.
